(19) United States
(12) Patent Application Publication
(10) Pub. No.: US 2012/0047731 A1
(43) Pub. Date: Mar. 1, 2012

(54) Method for Manufacturing Circuit Board and Method for Manufacturing Structure Using the Same

(75) Inventors: Tomohisa Murakami, Shiga (JP); Takayuki Umemoto, Shiga (JP)

(73) Assignee: KYOCERA CORPORATION, Kyoto (JP)

(21) Appl. No.: 13/223,007

(22) Filed: Aug. 31, 2011

(30) Foreign Application Priority Data
Aug. 31, 2010 (JP) JP2010193189
Aug. 30, 2011 (JP) JP2011187760

(51) Int. Cl. H05K 3/00

(52) U.S. Cl. 29/852

(57) ABSTRACT

According to one embodiment of the invention, a method for manufacturing a circuit board comprises forming a plurality of electroplated layers arranged apart from each other in a planer view on an underlying layer, wherein each of the electroplated layers comprises a first layer formed on the underlying layer by direct current electroplating, a second layer formed on the first layer by periodic reverse electroplating and a third layer, which is the outermost layer of the electroplated layer, formed on the second layer by direct current electroplating; etching a portion of the underlying layer between the electroplated layers in the planer view; forming an insulating layer on the third layer; forming a penetrating hole through the insulating layer to expose a part of the third layer at the bottom surface of the penetrating hole; forming a sputtered layer on an inner wall surface and the bottom surface of the penetrating hole.

### CROSS-REFERENCE TO RELATED APPLICATION

The present application claims priority under 35 U.S.C. §119 to Japanese Patent Application No. 2010-193189, filed on Aug. 31, 2010, entitled “METHOD FOR MANUFACTURING CIRCUIT BOARD AND METHOD FOR MANUFACTURING STRUCTURE USING THE SAME” and Japanese Patent Application No. 2011-187760, filed on Aug. 30, 2011, entitled “METHOD FOR MANUFACTURING CIRCUIT BOARD AND METHOD FOR MANUFACTURING STRUCTURE USING THE SAME”. The content of which is incorporated by reference herein in its entirety.

### BACKGROUND OF THE INVENTION

1. Field of the Invention

The present invention relates to a method for manufacturing a circuit board used for electronic devices (for example, various audio visual devices, household electrical appliances, communication devices, computer devices and peripheral devices thereof), etc., and a method for manufacturing a structure using the same.

2. Description of the Related Art

In general, structures each including electronic components mounted on a circuit board are used as mounting structures in electronic devices.

Japanese Unexamined Patent Application Publication No. 2009-188324 discloses a method for manufacturing a circuit board, the method including a step of forming a pad by a semi-additive method, a step of forming an insulating layer on the pad, a step of forming an opening in the insulating layer and exposing the upper surface of the pad in the opening, and a step of forming an adhesive layer on the surface of the insulating layer, which constitutes the opening, and the upper surface of the pad by a sputtering method.

However, when the pad is formed by the semi-additive method, crystal grain boundaries of a metal constituting the upper surface of the pad are easily etched with an etching solution used for etching an underlying layer, thereby easily forming recesses in the crystal grain boundaries. In this case, when the adhesive layer is formed on the upper surface of the pad by the sputtering method, it is difficult for particles scattered from a target to the upper surface of the pad to reach the insides of the recesses of the crystal grain boundaries, and thus the inner walls of the recesses are not easily coated with the adhesive layer. Therefore, the pad is easily separated from the adhesive layer, and thus disconnection easily occurs between the pad and a penetrating conductor, thereby easily degrading the electric reliability of a circuit board.

### BRIEF SUMMARY OF THE INVENTION

In response to the requirement for improving electric reliability, the present invention provides a method for manufacturing a circuit board and a method for manufacturing a structure using the same.

According to one embodiment of the invention, a method for manufacturing a circuit board comprises forming a plurality of electroplated layers arranged apart from each other in a planer view on an underlying layer, wherein each of the electroplated layers comprises a first layer formed on the underlying layer by direct current electroplating, a second layer formed on the first layer by periodic reverse electroplating and a third layer, which is the outermost layer of the electroplated layer, formed on the second layer by direct current electroplating; etching a portion of the underlying layer between the electroplated layers in the planer view; forming an insulating layer on the third layer; forming a penetrating hole through the insulating layer to expose a part of the third layer at the bottom surface of the penetrating hole; forming a sputtered layer on an inner wall surface and the bottom surface of the penetrating hole.

According to another embodiment of the invention, a method for manufacturing a structure comprises connecting an electronic component electrically to the circuit board.

### BRIEF DESCRIPTION OF THE DRAWINGS

FIG. 1A is a sectional view of a structure according to an embodiment of the present invention, taken along a thickness direction, and FIG. 1B is an enlarged sectional view showing portion R1 of the structure shown in FIG. 1A.

FIG. 2 is an enlarged sectional view showing portion R2 of the structure shown in FIG. 1B.

FIGS. 3A, 3B, 3C, and 3D are sectional views each illustrating a step for manufacturing the structure shown in FIG. 1A, taken along a thickness direction.

FIGS. 4A, 4B, and 4C are enlarged sectional views each illustrating a step for manufacturing the structure shown in FIG. 1A and showing a portion corresponding to portion R3 in FIG. 3C.

FIG. 5A is a timing chart of a direct-current electroplating method in a step for manufacturing the structure shown in FIG. 1A, and FIG. 5B is a timing chart of a reverse electroplating method in a step for manufacturing the structure shown in FIG. 1A.

FIG. 6A and 6B are sectional views each illustrating a step for manufacturing the structure shown in FIG. 1A, taken along a thickness direction.

FIGS. 7A and 7B are enlarged sectional views each illustrating a step for manufacturing the structure shown in FIG. 1A and showing a portion corresponding to portion R4 in FIG. 6B.

FIGS. 8A and 8B are sectional views each illustrating a step for manufacturing the structure shown in FIG. 1A, taken along a thickness direction.

### REFERENCE NUMERALS

1 structure
2 electronic component
3 circuit board
4 bump
5 core substrate
6 wiring layer
7 substrate
8 through hole conductor
9 insulator
10 insulating layer
10a first resin layer
10b second resin layer
11 conductive layer
11a first conductive layer
11b second conductive layer
12 penetrating conductor
13 electroless plated layer
14 electroplated layer
15a first layer
15b second layer
15c third layer
16 sputtered layer
16a first sputtered layer
16b second sputtered layer
T through hole
P penetrating hole

### DETAILED DESCRIPTION OF EXEMPLARY EMBODIMENTS

An example of a method for manufacturing a structure using a method for manufacturing a circuit board according to an exemplary embodiment of the present invention is described below on the basis of the drawings.

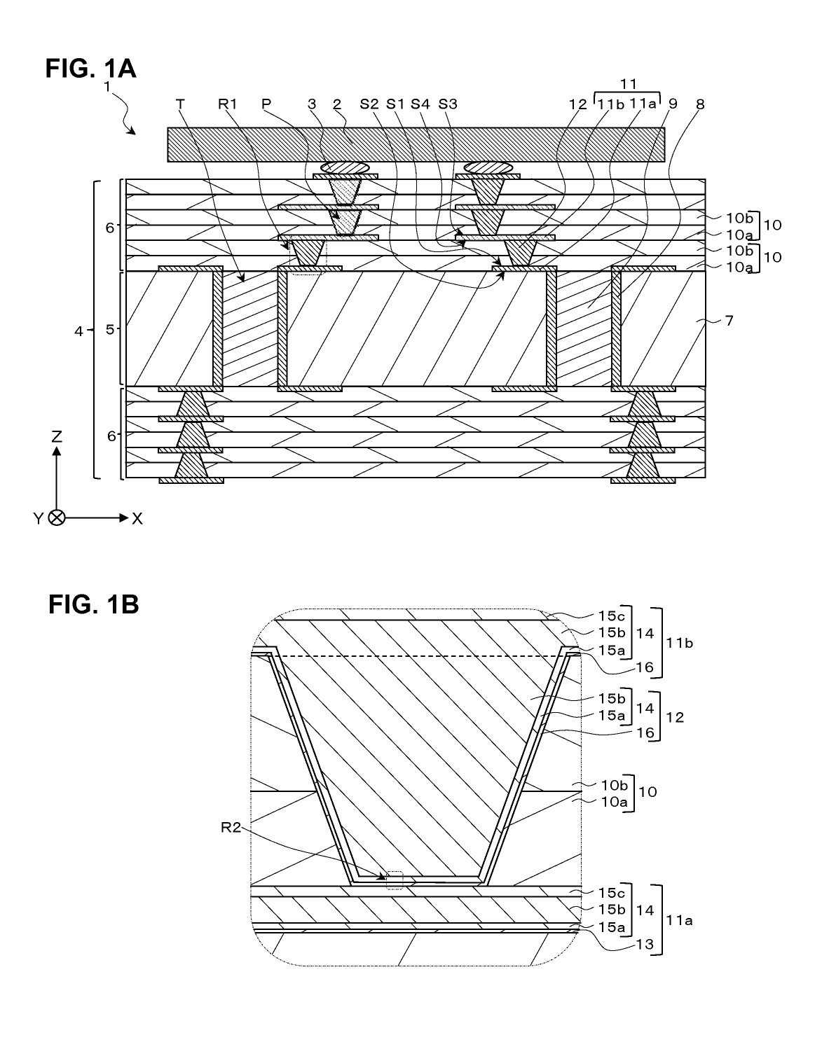

A structure 1 shown in FIG. 1(a) is formed using a method for manufacturing a structure according to an exemplary embodiment of the present invention, and is used for, for example, electronic devices, such as various audio visual devices, household electrical appliances, communication devices, computer devices or peripheral devices thereof, etc. The structure 1 includes an electronic component 2 and a circuit board 4 on which the electronic component 2 is flip-chip mounted via bumps 3.

The electronic component 2 is a semiconductor element, for example, IC or LSI, and includes a base material made of a semiconductor material, for example, silicon, germanium, gallium arsenide, gallium arsenide phosphide, gallium nitride, or silicon carbide. The thickness of the electronic component 2 is determined to, for example, 0.1 mm or more and 1 mm or less. In addition, the coefficient of thermal expansion of the electronic part 2 in each direction is determined to, for example, 3 ppm/° C. or more and 5 ppm/° C. or less. The coefficient of thermal expansion of the electronic component 2 is measured by a measurement method using a commercial TMA apparatus according to JIS K7197-1991. Hereinafter, the coefficient of thermal expansion of each member is measured by the same method as that for the electronic component 2.

The bumps 3 are each composed of a conductive material such as solder containing, for example, lead, tin, silver, gold, copper, zinc, bismuth, indium, or aluminum.

The circuit board 4 includes a core substrate 5 and a pair of wiring layers 6 formed above and below the core substrate 5.

The core substrate 5 is adapted for increasing the strength of the circuit board 4 and includes a substrate 7 having through holes T formed along the thickness direction, a cylindrical through hole conductor 8 formed in each of the through holes T, and a columnar insulator 9 formed in a region surrounded by the through hole conductor 8.

The substrate 7 constitutes a principal portion of the core substrate 5 to enhance rigidity and includes a resin portion, a base material coated with the resin portion, and an inorganic insulating filler coated with the resin portion. The thickness of the substrate 7 is determined to, for example, 0.1 mm or more and 1 mm or less. The coefficient of thermal expansion of the substrate 7 in the planar direction is determined to, for example, 5 ppm/° C. or more and 30 ppm/° C. or less, and the coefficient of thermal expansion of the substrate 7 in the thickness direction is determined to, for example, 15 ppm/° C. or more and 50 ppm/° C. or less. The substrate 7 need not necessarily contain the base material or the inorganic insulating filler.

The resin portion of the substrate 7 is composed of a thermosetting resin, for example, an epoxy resin, a bismaleimide triazine resin, a cyanate resin, a polyphenylene ether resin, a wholly aromatic polyamide resin, or a polyimide resin. The resin portion may be composed of a thermoplastic resin, for example, a fluorocarbon resin, an aromatic liquid crystal polyester resin, a polyether ketone resin, a polyphenylene ether resin, or a polyimide resin.

As the base material of the substrate 7, a woven fabric or nonwoven fabric composed of fibers, or a material formed by arranging fibers in a direction can be used. In addition, usable examples of fibers constituting the base material include glass fibers, resin fibers, carbon fiber, metal fibers, and the like.

The inorganic insulating filler of the substrate 7 is provided for enhancing the rigidity and decreasing thermal expansion of the substrate 7 and is composed of a plurality of particles made of an inorganic insulating material, for example, silicon oxide or the like.

The through hole conductor 8 is provided for electrically connecting the wiring layers 6 on the main surfaces of the core substrate 5 and disposed on the inner wall of each of the through holes T to have the same configuration as that of first conductive layers 11a described below.

The insulator 9 is provided for supporting a penetrating conductor 12 described below and is composed of a resin material, for example, a polyimide resin, an acrylic resin, an epoxy resin, a cyanate resin, a fluorocarbon resin, a silicone resin, a polyphenylene ether resin, or a bismaleimide triazine resin.

On the other hand, as described above, a pair of wiring layers 6 are formed on the main surfaces of the core substrate 5. The wiring layers 6 each include an insulating layer 10 having penetrating holes P formed along the thickness direction, conductive layers 11 formed on the substrate 7 or the insulating layer 10, and the penetrating conductor 12 formed in each of the penetrating holes P and connected to the conductive layers 11.

The insulating layer 10 functions as an insulating member which prevents short-circuiting between the conductive layers 11 and includes a first resin layer 10a and a second resin layer 10b disposed nearer to the core substrate 5 side than the first resin layer 10a. The thickness of the insulating layer 10 is determined to, for example, 5 μm or more and 40 μm or less.

The first resin layer 10a is provided for enhancing rigidity of the insulating layer 10 and decreasing the coefficient of thermal expansion of the insulating layer 10 in the planar direction, and includes a resin portion and an inorganic insulating filler coated with the resin portion. The thickness of the first resin layer 10a is determined to, for example, 2 μm or more and 20 μm or less. The coefficient of thermal expansion of the first resin layer 10a in the planar direction is determined to, for example, 0 ppm/° C. or more and 30 ppm/° C. or less, and the coefficient of thermal expansion of the first resin layer 10a in the thickness direction is determined to, for example, 20 ppm/° C. or more and 50 ppm/° C. or less. The first resin layer 10a need not necessarily contain the inorganic insulating filler.

The resin portion of the first resin layer 10a is composed of a thermoplastic resin, for example, a polyimide resin. Using such a thermoplastic resin can increase the rigidity of the first resin layer 10a and decrease the coefficient of thermal expansion thereof. The resin portion contained in the first resin layer 10a preferably has a film shape having a structure in which resin molecular chains have the same longitudinal direction. As a result, the coefficient of thermal expansion in the planar direction can be decreased.

The inorganic insulating filler of the first resin layer 10a is provided for increasing the rigidity of and decreasing the thermal expansion of the first resin layer 10a and is composed of, for example, the similar material to the inorganic insulating filler of the above-described substrate 7.

The second resin layer 10b is provided for bonding the first resin layers 10a adjacent in the thickness direction or the substrate 7 and the first resin layer 10a and for fixing the conductive layers 11 by bonding to the sides and a main surfaces of the conductive layers 11. The second resin layer 10b includes a resin portion and an inorganic insulating filler coated with the resin portion. The thickness of the second resin layer 10b is determined to, for example, 2 μm or more and 20 μm or less. The coefficient of thermal expansion of the second resin layer 10b in each of the directions is determined to, for example, 10 ppm/° C. or more and 40 ppm/° C. or less. The second resin layer 10b need not necessarily contain the inorganic insulating filler.

The resin portion of the second resin layer 10b is composed of a thermosetting resin, for example, an epoxy resin, a bismaleimide triazine resin, a cyanate resin, or an amide resin. Using such a thermosetting resin can strongly bond the first resin layers 10a adjacent in the thickness direction or bond the substrate 7 and the first resin layer 10a.

The inorganic insulating filler of the second resin layer 10b is provided for increasing the rigidity and decrease the thermal expansion of the second resin layer 10b and is composed of, for example, a plurality of particles made of the similar material to the inorganic insulating filler of the above-described substrate 7.

The conductive layers 11 function as grounding wiring, electric power supplying wiring, or signal wiring, and the side surface and one of the main surfaces are bonded to the second resin layer 10b, the other main surface being bonded to the substrate 7 or the first resin layer 10a. In addition, the main surfaces of the conductive layer 11 are partially connected to each of the penetrating conductors 12. The conductive layers 11 each includes a first conductive layer 11a formed on the substrate 7 and a second conductive layer 11b formed on the first resin layer 10a.

As shown in FIG. 1(b), the first conductive layer 11a includes an electroless plated layer 13 formed on the substrate 7 by an electroless plating method, and an electroplated layer 14 formed on the electroless plated layer 13 by an electroplating method. The thickness of the first conductive layer 11a is determined to, for example, 8.5 μm or more and 10.5 μm or less. The arithmetic mean roughness (Ra) of one S1 (main surface bonded to the second resin layer 10b) of the main surfaces of the first conductive layer 11a is determined to, for example, 0.1 μm or more and 0.5 μm less, and the arithmetic mean roughness of the other main surface S2 (the other main surface bonded to the substrate 7) of the main surfaces of the first conductive layer 11a is determined to, for example, 0.5 μm or more and 2 μm or less. The arithmetic mean roughness is determined according to ISO 4287: 1997.

The arithmetic mean roughness (Ra) of the main surface S1 of the first conductive layer 11a is preferably smaller than the arithmetic mean roughness of the other main surface S2 of the first conductive layer 11a. As a result, when the main surface S1 of the first conductive layer 11a has smaller arithmetic mean roughness, as described below, the adhesive strength between the first conductive layer 11a and the sputtered layer 16 can be enhanced, while the adhesive strength between the first conductive layer 11a and the substrate 7 can be enhanced due to the anchor effect caused by the smaller arithmetic mean roughness of the other main surface S2 of the first conductive layer 11a.

The electroless plated layer 13 of the first conductive layer 11a is interposed between the substrate 17 and the electroplated layer 14 and functions as an underlying layer of the electroplated layer 14. The electroless plated layer 13 is formed of, for example, copper. In addition, the electroless plated layer 13 may further contain phosphorus, palladium, or tin other than copper. The thickness of the electroless plated layer 13 is determined to, for example, 0.3 μm or more and 0.5 μm or less.

The electroplated layer 14 of the first conductive layer 11a constitutes a main portion of the first conductive layer 11a and is formed of a high-conductivity material, such as copper. The electroplated layer 14 includes a first layer 15a formed on the electroless plated layer 13 by a direct-current electroplating method, a second layer 15b formed on the first layer 15a by a reverse electroplating method, and a third layer 15c formed as the outermost layer on the second layer 15b by a direct-current electroplating method. The thickness of the electroplated layer 14 is determined to, for example, 7.5 μm or more and 13 μm or less. In the electroplated layer 14, the first layer 15a, the second layer 15b, and the third layer 15c can be distinguished by observing, with a scanning ion microscope, the crystal state of a section of the electroplated layer 14 taken along a thickness direction.

The first layer 15a of the electroplated layer 14 is interposed between the electroless plated layer 13 and the second layer 15b. The first layer 15a is deposited more densely on the surface of the underlying layer than the second layer 15b and thus has high adhesive strength to the electroless plated layer 13. In addition, the first layer and the second layer 15b are continuously formed by the electroplating method as described below and thus have high adhesive strength therebetween. Therefore, the first layer 15a can enhance the adhesive strength between the electroless plated layer 13 and the second layer 15b, and thus it is possible to decrease separation between the electroless plated layer 13 and the electroplated layer 14, thereby decreasing disconnection of the conductive layer 11. The thickness of the first layer 15a is determined to, for example, 0.8 μm or more and 1.2 μm or less.

The second layer 15b of the electroplated layer 14 constitutes a main portion of the electroplated layer 14. The second layer 15b can be easily formed to a uniform thickness as compared with a direct-current electroplated layer as described below. Therefore, the thickness of the conductive layer 11 can be made uniform by the second layer 15b, and thus disconnection of the conductive layer 11 due to variation in thickness of the conductive layer 11 can be decreased. The thickness of the second layer 15b is determined to, for example, 5.5 μm or more and 6.5 μm or less.

The third layer 15c of the electroplated layer 14 constitutes the one main surface S2 of the first conductive layer 11a and is a member to which each of the penetrating conductors 12 is connected. The third layer 15c has a larger crystal grain diameter and less crystal grains than the second layer 15b, and thus it is difficult to produce cracking because of high ductility. Therefore, when stress is applied to one main surface of the conductive layer, cracking of the conductive layer 11 can be decreased by the third layer 15c, and thus disconnection of the conductive layer 11 can be decreased. The thickness of the third layer 15c is determined to, for example, 1.5 μm or more and 2.5 μm or less.

The second conductive layer 11b includes a sputtered layer 16 formed on the first resin layer 10a by a sputtering method and an electroplated layer 14 formed on the sputtered layer 16 by an electroplating method. The thickness of the second conductive layer 11b is determined to, for example, 4.5 μm or more and 6.5 μm or less. In addition, the arithmetic mean roughness of a main surface S3 (one main surface bonded to the second resin layer 10b) of the second conductive layer 11b is determined to, for example, 0.1 μm or more and 2 μm or less, and the arithmetic mean roughness of the other main surface S4 (the other main surface bonded to the first resin layer 10a) of the second conductive layer 11b is determined to, for example, 0.01 μm or more and 1 μm or less.

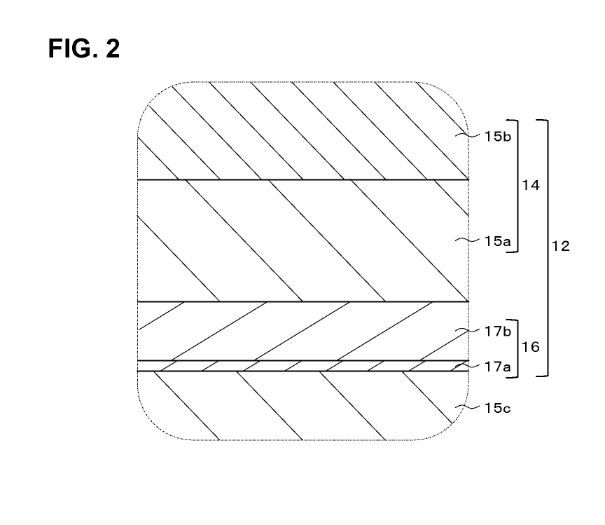

The sputtered layer 16 of the second conductive layer 11b is interposed between the first resin layer 10a and the electroplated layer 14 and functions as an underlying layer of the electroplated layer 14. In this case, by using the sputtered layer 16 as the underlying layer, the underlying layer having high adhesive strength to the first resin layer 10a can be formed without roughening the first resin layer 10a as compared with a case in which the electroless plated layer 13 is used as the underlying layer. Therefore, the first resin layer 10a is not roughened, and thus the second conductive layer 11b in the wiring layer 6 can be made fine. As shown in FIG. 2, the sputtered layer 16 includes a first sputtered layer 16a formed on the first resin layer 10a by a sputtering method, and a second sputtered layer 16b formed on the first sputtered layer 16a by a sputtering method. The thickness of the sputtered layer 16 is determined to, for example, 0.55 μm or more and 0.6 μm or less.

The first sputtered layer 16a is bonded to the first resin layer 10a and is formed of, for example, a conductive material such as a nickel-chromium alloy or titanium. Since the first sputtered layer 16a is made of such a conductive material, the first sputtered layer 16a has high adhesive strength to the first resin layer 10a composed of a thermoplastic resin. Therefore, the first sputtered layer 16a can enhance the adhesive strength between the first resin layer 10a and the sputtered layer 16. The thickness of the first sputtered layer 16a is determined to, for example, 0.07 μm or more and 0.08 μm or less.

The second sputtered layer 16b is interposed between the first sputtered layer 16a and the electroplated layer 14 and is formed of copper. Since the second sputtered layer 16b is made of copper which is the similar material to the electroplated layer 14, the second sputtered layer 16b has high adhesive strength to the electroplated layer 14. In addition, the first sputtered layer 16a and the second sputtered layer 16b are continuously formed by a sputtering method as described below and thus have high adhesive strength therebetween. Therefore, the second sputtered layer 16b can enhance the adhesive strength between the sputtered layer 16 and the electroplated layer 14. The thickness of the second sputtered layer 16b is determined to, for example, 0.48 μm or more and 0.52 μm or less.

Like the above-described electroplated layer 14 of the first conductive layer 14a, the electroplated layer 14 of the second conductive layer 11b includes the first layer 15a, the second layer 15b, and the third layer 15c.

The thickness of the second layer 15b in the second conductive layer 11b is smaller than that of the second layer 15b of the first conductive layer 11a. As a result, the second layer 15b of the first conductive layer 11a has a larger thickness, and thus it is possible to increase reliability by increasing the thickness of the through hole conductors 8 formed. At the same time as the first conductive layer 11b, it is possible to increase the wiring density in the wiring portion 6 by increasing the thickness of the second layer 15b in the second conductive layer 11b, thereby decreasing the thickness of the second conductor layer 11a. The thickness of the second layer 15b in the second conductive layer 11b is determined to, for example, 1.5 μm or more and 2.5 μm or less, and is thus determined to, for example, 30% or more and 40% or less of the thickness of the second layer 15b in the first conductive layer 11a.

The other configuration of the electroplated layer 14 of the second conductive layer 11b is similar to the electroplate layer 14 of the second conductive layer 11b.

The penetrating conductor 12 is adapted for connecting the conductive layers 11 spaced in the thickness direction, is formed into a taper shape with a width decreasing toward the core substrate 5, and connected to the corresponding conductive layer 11 at the bottom of the penetrating hole P. The penetrating conductor 12 includes a sputtered layer 16 formed on the inner wall and the bottom of the penetrating hole P, and an electroplated layer 14 formed on the sputtered layer 16. The sputtered layer 16 and the electroplated layer 14 of the penetrating conductor 12 have the similar configurations to the sputtered layer 16 and the electroplated layer 14, respectively, of the second conductive layer 11b.

In addition, when heat is applied to the circuit board, thermal stress is easily applied to connection positions between the conductive layers 11 and the penetrating conductors 12.

On the other hand, in the circuit board 3 of this embodiment, the penetrating conductor 12 is connected to the top of the third layer 15c of the corresponding conductive layer 11. Consequently, when thermal stress is applied to the connection positions between the conductive layer 11 and the penetrating conductor 12, cracking in the conductive layer 11 due to the thermal stress can be decreased because the third layer 15c has high ductility as described above. Therefore, disconnection of the conductive layer 11 can be decreased, thereby producing a circuit board having excellent electric reliability.

The thickness of the third layer 15c is preferably larger than the thickness of the first layer 15a. Consequently, since the third layer 15c has a larger thickness, the strength of the upper surface of the conductive layer 11 can be increased, and thus cracking in the conductive layer 11 due to thermal stress can be decreased, thereby decreasing disconnection in the conductive layer 11. In addition, since the first layer 15a has a smaller thickness, variation in thickness of the conductive layer 11 due to the direct-current electroplated layer can be decreased, thereby decreasing disconnection in the conductive layer 11. The thickness of the third layer 15c is determined to, for example, 1.5 times or more and 2.5 times or less the thickness of the first layer 15a.

In addition, the thickness of each of the first layer 15a and the third layer 15c is preferably smaller than the thickness of the second layer 15b. As a result, the ratio (% by volume) occupied by the second layer 15b in the conductive layer 11 can be increased, thereby decreasing variation in thickness of the conductive layer 11 and thus decreasing disconnection in the conductive layer 11. In the first conductive layer 11, the thickness of the first layer 15a is determined to, for example, 10% or more and 20% or less the thickness of the second layer 15b, and the thickness of the third layer 15c is determined to, for example, 35% or more and 45% or less the thickness of the second layer 15b. In the second conductive layer 11, the thickness of the first layer 15a is determined to, for example, 45% or more and 55% or less the thickness of the second layer 15b, and the thickness of the third layer 15c is determined to, for example, 75% or more and 125% or less the thickness of the second layer 15b.

Therefore, the above-described structure 1 exhibits a desired function by driving or controlling the electronic component 2 based on a power and signal supplied through the circuit board 4.

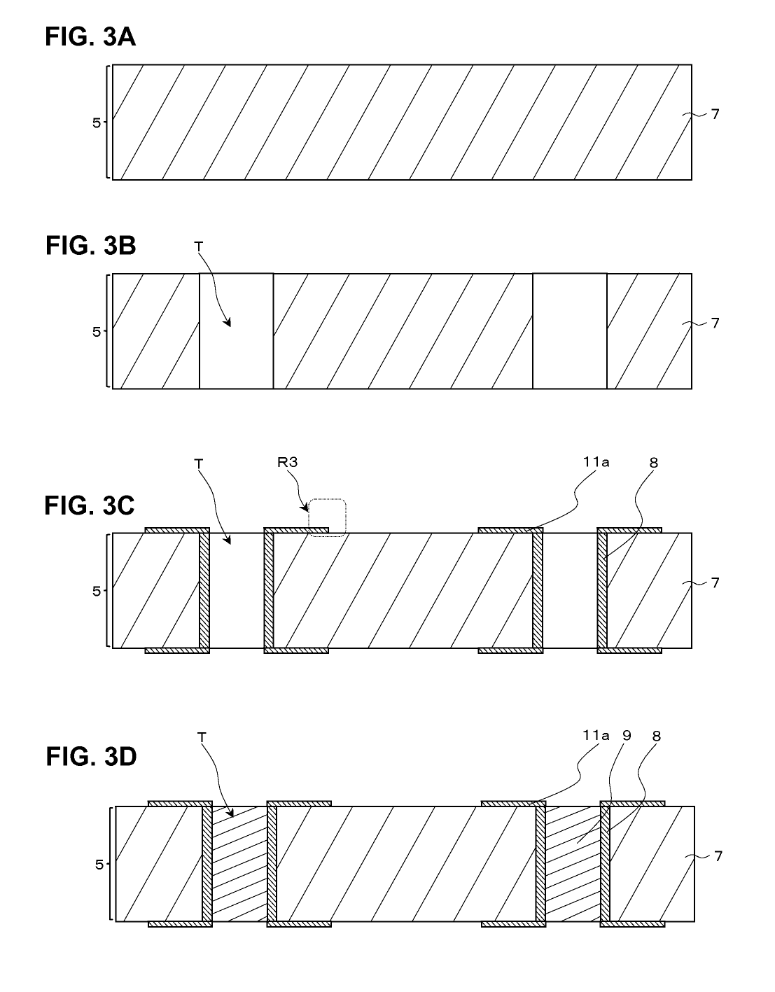

Next, the method for manufacturing the above-described structure 1 is described on the basis of FIGS. 3 to 7.

(1) As shown in FIGS. 3(a) and 3(b), the substrate 7 is formed, and the through holes T are formed in the substrate 7. Specifically, the substrate 7 and the through holes Tare formed, for example, as follows.

First, a plurality of resin sheets containing an uncured thermosetting resin are laminated, and the resultant laminate is heated under pressure to cure the thermosetting resin, forming the substrate 7. The uncured state is A-stage or B-stage according to ISO 472: 1999. Next, the through holes T passing through the substrate 7 in the thickness direction are formed by, for example, drilling or laser processing.

(2) As shown in FIG. 3(c), the through hole conductor 8 is formed in each of the through holes T, and as the same time, the first conductive layers 11a are formed on the substrate 7. Then, as shown in FIG. 3(d), the inside of the through hole conductors 8 are filled with a resin material to form the insulators 9. Specifically, the through hole conductors 8 and the first conductive layers 11a are formed, for example, as follows.

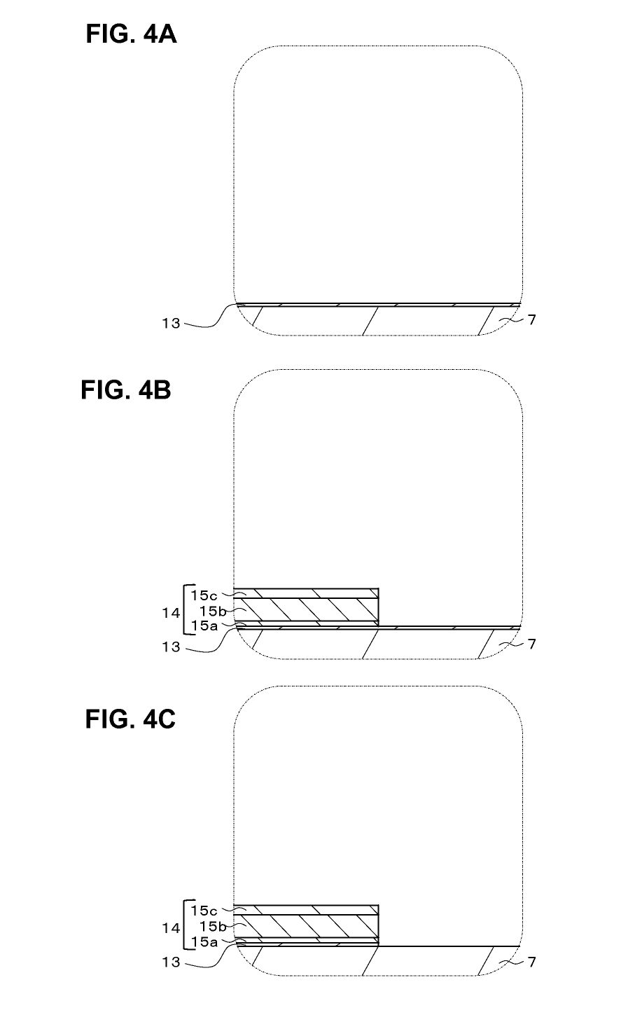

First, as shown in FIG. 4(a), copper is deposited on both main surfaces of the substrate 7 and the inner walls of the through holes T by an electroless plating method, thereby forming the electroless plated layers 13. Next, as shown in FIG. 4(b), the electroplated layer 14 is partially formed on each of the electroless plated layers 13 serving as the underlying layers on both main surfaces of the substrate 7. Next, as shown in FIG. 4(c), portions of the electroless plated layers 13, which are exposed from the electroplated layers 14, are etched along the thickness direction using an etching solution such as a mixed solution of a hydrogen peroxide solution and an aqueous sulfuric acid solution or a mixed solution of hydrochloric acid, nitric acid, and an aqueous ferric chloride solution, forming the first conductive layers 11a and the through hole conductors 8.

The method for forming the electroplated layers 14 of the embodiment is described in detail below.

First, copper is partially deposited on each of the electroless plated layers 13 to form the first layer 15a by a direct-current electroplating method using a direct current. Next, copper is deposited on the first layer 15a by a periodic reverse electroplating method (PR method) in which the direction of a current flow is alternately reversed, forming the second layer 15b. Next, copper is deposited on the second layer 15b by a direct-current electroplating method, forming the third layer 15c.

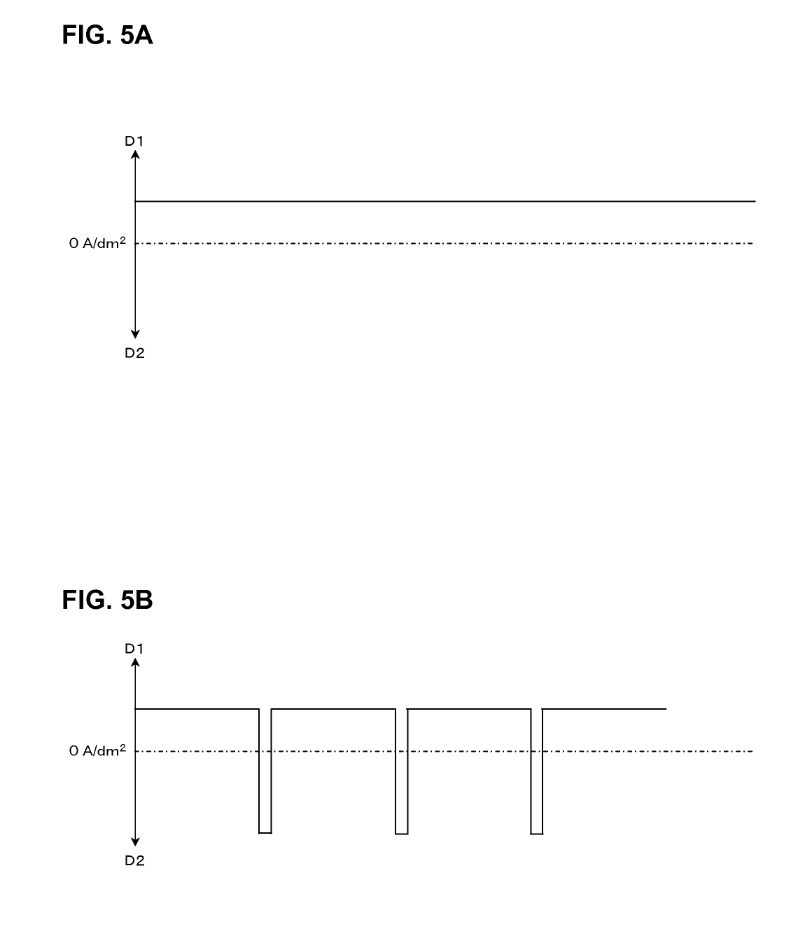

In the direct-current electroplating method, as shown in FIG. 5(a), a substantially constant current is passed in direction D1 in which the underlying layer serves as a cathode. Therefore, in the first layer 15a and the third layer 15c, copper crystals are continuously grown to larger crystals as compared with the second layer 15b in which copper crystals are intermittently grown, thereby forming fewer regions of crystal grain boundaries. Therefore, in the first layer 15a and the third layer 15c, when stress is applied as compared with the second layer 15b, cracking due to crystal grain boundaries is decreased, thereby causing little cracking. In the direct-current electroplating method, the current density is determined to, for example, 0.5 A/dm² or more and 2 A/dm² or less. In addition, the time required to pass the current for forming the first layer 15a (hereinafter referred to as “t1”) is determined to, for example, 2 minutes or more and 10 minutes or less. The time required to pass the current for forming the third layer 15c (hereinafter referred to as “t2”) is determined to, for example, 6 minutes or more and 27 minutes or less. Further, t1 is determined to be longer than t2 and, for example, 2 times or more and 5 times or less t2.

In addition, in the periodic reverse electroplating method, as shown in FIG. 5(b), the flow direction of a direct current is periodically alternately reversed. Specifically, first, the current is passed in the direction D1 in which the underlying layer serves as a cathode so that copper is deposited on the underlying layer by reduction of copper ions in a plating solution. Next, the direction of the current flow is reversed, and the current is passed in direction D2 in which the underlying layer serves as an anode so that copper ions are eluted from the underlying layer to the plating solution by oxidation of copper in the underlying layer. Next, the direction of the current is periodically alternately reversed. In this case, the product of the current density and pulse width when the underlying layer serves as a cathode is larger than the product of the current density and pulse width when the underlying layer serves as an anode so that the second layer 15b can be formed due to a larger amount of copper deposited than an amount of copper ions eluted.

Here, the current density in the case of the underlying layer serving as an anode is made higher than that in the case of the underlying layer serving as a cathode, and the pulse width in the case of the underlying layer serving as an anode is made shorter than that in the case of the underlying layer serving a cathode. Therefore, when the underlying layer serves as an anode, elusion of copper ions in a region having a large copper thickness can be increased. Thus, even when in the case of the underlying layer serving as a cathode, the current density is increased at the openings of the through holes to cause variation in thickness of the copper deposited on the underlying layer, the variation in thickness of the copper deposited on the underlying layer can be decreased by eluting a large amount of copper ions in a region having a large thickness of copper deposited when the underlying layer serves as an anode. Therefore, the second layer 15b can be formed so as to have a uniform thickness as compared with the first layer 15a and the third layer 15c.

In the periodic reverse electroplating method, when the underlying layer serves as an anode, the current density is determined to, for example, 1 A/dm² or more and 5 A/dm² or less, while when the underlying layer serves as a cathode, the current density is determined to, for example, 0.5 A/dm² or more and 2 A/dm² or less. In addition, in the periodic reverse electroplating method, when the underlying layer serves as an anode, the pulse width is determined to, for example, 0.5 ms or more and 3 ms or less, while when the underlying layer serves as a cathode, the pulse width is determined to, for example, 10 ms or more and 30 ms or less.

As described above, the electroplated layers 14 each including the first layer 15a, the second layer 15b, and the third layer 15c and having a main surface in which the third layer 15c is exposed can be formed. In each of the thus-formed electroplated layers 14, the first layer 15a can enhance the adhesive strength to the electroless plated layer 13 serving as the underlying layer, the second layer 15b can achieve a more uniform thickness and increase flatness, and the third layer 15c can decrease a region where crystal grain boundaries are formed in the exposed main surface.

In addition, when portions of the electroless plated layer 13, which are exposed from the electroplated layers 14, are etched along the thickness direction by using an etching solution, the exposed main surfaces of the electroplated layers 14 are immersed in the etching solution. As a result, crystal grains in the exposed main surfaces are more etched with the etching solution than in the other regions, thereby easily forming recesses in the crystal gain boundaries.

On the other hand, in the method for manufacturing the circuit board 4 according to the embodiment, as described above, the region where crystal grain boundaries are formed in the exposed main surface of the electroplated layer 14 is decreased by the third layer 15c, and thus the formation of recesses due to the etching solution can be decreased, and consequently the first conductive layer 11a can be formed with flatness increased by decreasing the formation of recesses in the exposed main surface.

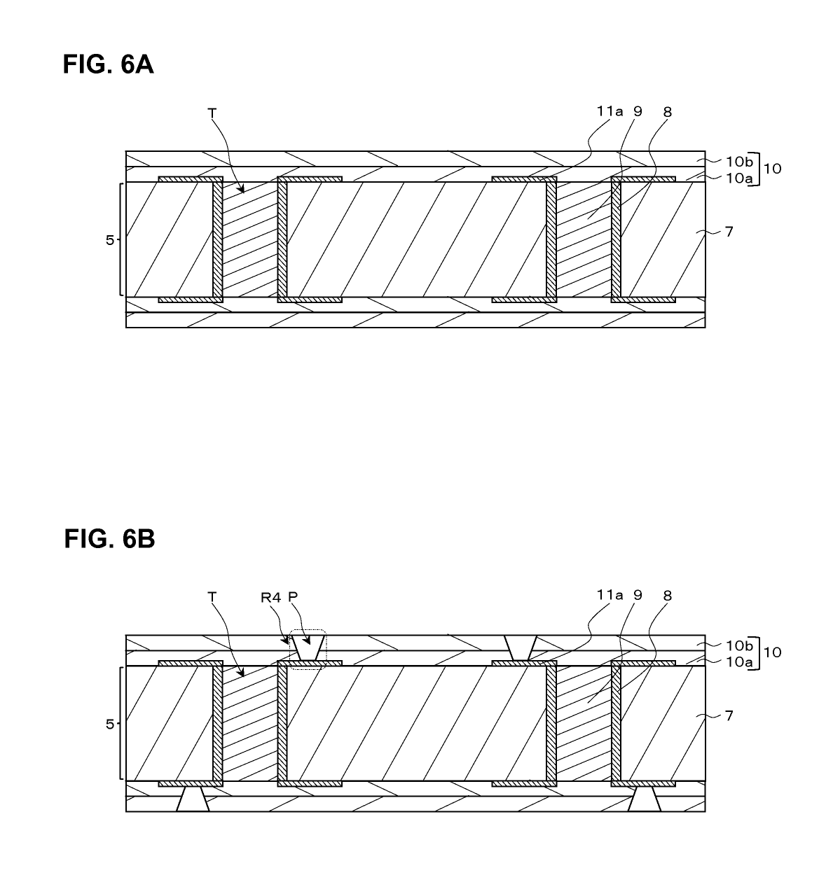

(3) As shown in FIGS. 6(a) and 6(b), the insulating layer 10 is formed on the first conductive layers 11a, and the penetrating holes P are formed in the insulating layer 10. Specifically, for example, the insulating layer 10 and the penetrating holes P are formed, for example, as follows.

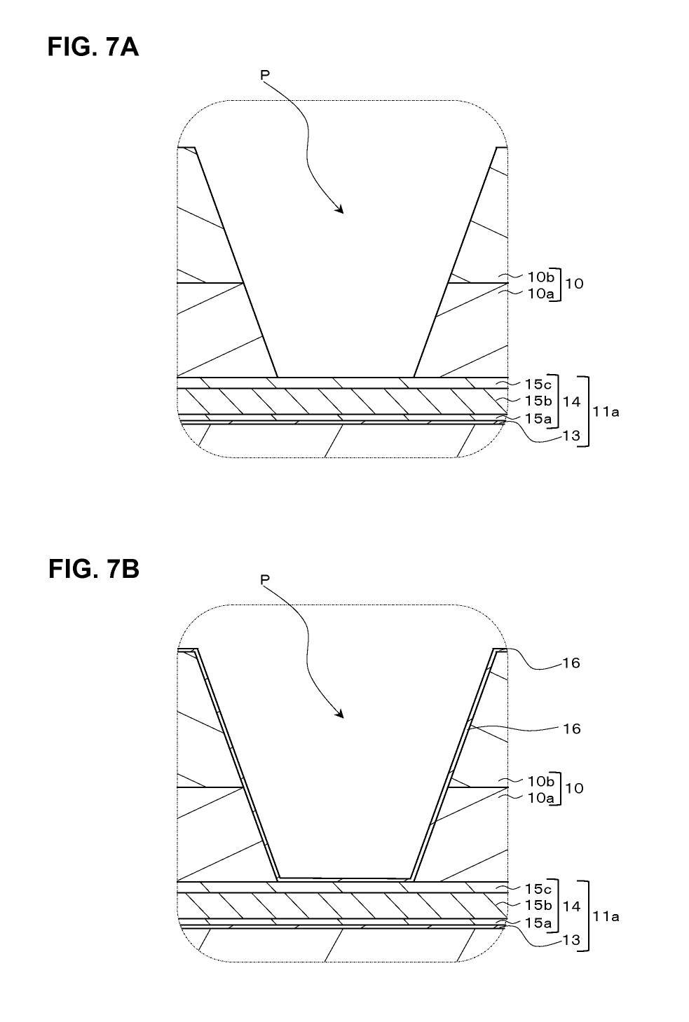

First, the film-shaped first resin layer 10a is disposed on the third layers 15c of the first conductive layers 11a through the second resin layer 10b containing an uncured thermosetting resin, and then the core substrate 7, the second resin layer 10b and the first resin layer 10a are heated under pressure to cure the thermosetting resin of the second resin layer 10b, thereby forming the insulating layer 10 on the third layers 15c of the first conductive layers 11a. Next, the penetrating holes P are formed in the insulating layer 10 by, for example, a YAG laser apparatus or a carbon dioxide gas laser apparatus to expose the third layer 15c of the first conductive layer 11a at the bottom of each of the penetrating holes P. As shown in FIG. 7(a), the exposed third layer 15c constitutes the main surface of the first conductive layer 11a exposed at the bottom of the each of the penetrating holes P.

(4) As shown in FIG. 7(b), the first sputtered layer 16a and the second sputtered layer 16b are sequentially deposited on the first resin layer 10a and the inner walls of and the bottoms of the penetrating holes P by using a sputtering apparatus, thereby forming the sputtered layer 16.

In the method for manufacturing the circuit board 4 according to the embodiment, in the step (2), the formation of recesses due to the etching solution in the main surface of each of the first conductive layers 11a, which is exposed at the bottom of the penetrating hole P, is decreased. As a result, a larger region of the main surface of each of the first conductive layer 11a, which is exposed at the bottom of each of the penetrating holes P, can be coated with the sputtered layer 16, and thus adhesive strength between the first conductive layers 11a and the sputtered layer 16 can be enhanced. Also, disconnection between the first conductive layers 11a and the via conductors 12 can be decreased, thereby achieving the circuit board 4 having excellent electric reliability.

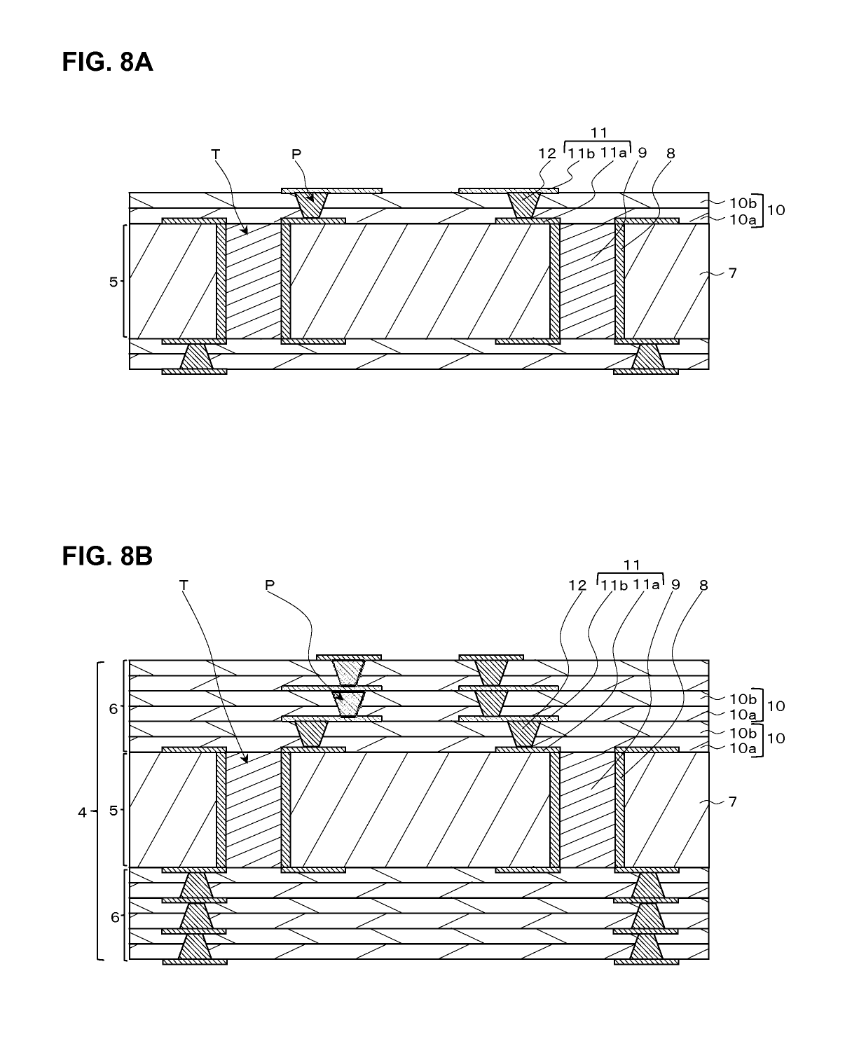

(5) As shown in FIG. 8(a), the electroplated layer 14 is partially formed on the sputtered layer 16 serving as the underlying layer, and portions of the sputtered layer 16, which are exposed from the electroplated layers 14, are etched in the thickness direction to form the penetrating conductor 12 in each of the penetrating holes P and form the second conductive layers lib on the first resin layer 10a. Specifically, the similar step to the step (2) can be performed.

(6) As shown in FIG. 8(b), the steps (3) to (5) are repeated to form the wiring layer 6, forming the circuit board 4.

(7) The structure 1 shown in FIG. 1 can be manufactured by flip-chip mounting the electronic component 2 on the circuit board 4 through the bumps 3.

The present invention is not limited to the above-described embodiment, and various changes, modifications, and combinations can be made within the scope of the gist of the present invention.

For example, in the above-described embodiment of the present invention, the wiring layer including the three insulating layers is formed, but one, two, or four insulating layers may be provided.

In addition, in the above-described embodiment, the insulating layers including both the first resin layer and the second resin layer is used, but the insulating layers may include only the second resin layer or may be composed of other resin layers.

In addition, in the above-described embodiment, the third layer is formed in each of the first conductive layer and the second conductive layer, but the third layer may be formed in any one of the first conductive layer and the second conductive layer.

Further, in the above-described embodiment, the penetrating conductors are filled with an electroplated layer, but the penetrating conductors may not be filled with an electroplated layer, and the electroplated layer may be formed as a coated film.

Further, in the above-described embodiment, the electroless plated layer and the sputtered layer are used as the underlying layers of the electroplated layers, but the underlying layer may be formed by, for example, a vapor deposition method other than the sputtering method as long as the underlying layer functions as a base for an electroplated layer.

Further, in the above-described embodiment, the sputtered layer includes both the first sputtered layer and the second sputtered layer, but the sputtered layer may include only one of the first sputtered layer and the second sputtered layer.

What is claimed is:

1. A method for manufacturing a circuit board comprising:
forming a plurality of electroplated layers arranged apart from each other in a planer view on an underlying layer, wherein each of the electroplated layers comprises a first layer formed on the underlying layer by direct current electroplating, a second layer formed on the first layer by periodic reverse electroplating and a third layer, which is the outermost layer of the electroplated layer, formed on the second layer by direct current electroplating;
etching a portion of the underlying layer between the electroplated layers in the planer view;
forming an insulating layer on the third layer;
forming a penetrating hole through the insulating layer to expose a part of the third layer at the bottom surface of the penetrating hole; and
forming a sputtered layer on an inner wall surface of and the bottom surface of the penetrating hole.

2. The method for manufacturing the circuit board according to claim 1, wherein the third layer is thicker than the first layer.

3. The method for manufacturing the circuit board according to claim 1, wherein the second layer is thicker than each the first layer and the third layer.

4. The method for manufacturing the circuit board according to claim 1, wherein each the first layer, the second layer and the third layer comprise copper.

5. A method for manufacturing a structure comprising:
connecting an electronic component electrically to a circuit board manufactured by the method according to claim 1.
